(19) United States
(12) Patent Application Publication
(10) Pub. No.: US 2012/0169718 A1
(43) Pub. Date: Jul. 5, 2012

(54) THREE DIMENSIONAL DISPLAY STRUCTURE

(76) Inventor: Melvin Schindler, Piscataway, NJ (US)

(21) Appl. No.: 13/171,126

(22) Filed: Jun. 28, 2011

Related U.S. Application Data
(60) Provisional application No. 61/398,558, filed on Jun. 28, 2010.

(51) Int. Cl. G06T 15/00; H05K 13/00

(52) U.S. Cl. 345/419; 29/592.1

(57) ABSTRACT

A three dimensional display system presents a physical three dimensional representation of a two dimensional image. The display system includes multiple display portions where each portion subsumes at least a portion of the two dimensional image. The display portions are arranged in a nested stacked and spaced arrangement, such that the portions of the two dimensional image depicted on the display portions are congruent.

### CROSS-REFERENCE TO RELATED APPLICATION

This application claims priority to U.S. Provisional Application No. 61/398,558, titled METHOD FOR PRODUCING A THREE DIMENSIONAL REPRESENTATION OF AN IMAGE BY THE LAYERED ASSEMBLY OF NESTED SERIAL IMAGE SEGMENTS DERIVED FROM A TWO DIMENSIONAL PHOTOGRAPH, and filed on Jun. 28, 2010, the disclosure of which is hereby incorporated by reference in its entirety.

### BACKGROUND

Two dimensional images compress the three dimensionality of a subject. Although a variety of techniques have been developed that attempt to retain sufficient data at the time the image is captured to re-create the third dimension for the viewer, these techniques require specialized image capture or presentation devices, such as three dimensional cameras or lenticular lenses, respectively. Three dimensional movies and television are also becoming popular, but require the use of specialized video equipment and computers to manipulate the captured image in an effort to create the illusion of three dimensions for the viewer. This generally requires the observer to wear special eye gear. An improved system for displaying a two dimensional image in three dimensions is desired that is independent of specialized equipment for image capturing and viewing and preferably produces a physical re-creation of the image in three dimensions.

### SUMMARY

In general terms, this disclosure is directed to a three dimensional display structure and methods of making same. In one possible configuration and by non-limiting example, the display structure includes multiple display portions that are all formed of portions of the same original image. The display portions are arranged in a stacked and spaced configuration in which different regions of the original image are visible on different display portions, to provide a unique three dimensional presentation.

One aspect is a display structure for displaying a two dimensional image in three dimensions, the structure comprising: a first display portion having a substantially planar first surface, the first surface having a first area and depicting thereon at least a portion of the two dimensional image; a second display portion having a substantially planar second surface substantially parallel to and spaced from the first surface, the second surface having a second area less than the first area and depicting thereon at least the portion of the two dimensional image; and a third display portion having a substantially planar third surface substantially parallel to and spaced from the second surface, the third surface having a third area less than the second area and depicting thereon at least the portion of the two dimensional image, wherein the portions of the two dimensional image depicted on the first, second, and third display portions are aligned with each other.

Another aspect is a method of making a display structure for displaying a two dimensional image in three dimensions, the method comprising: obtaining the two dimensional image; generating a plurality of differently sized display portions from copies of the two dimensional image; and arranging the display portions in a nested stack and spaced arrangement in which the display portions are substantially congruent.

### BRIEF DESCRIPTION OF THE DRAWINGS

FIG. 1 is a perspective view of an example three dimensional display system including a three dimensional display structure.

FIG. 2 is a schematic front plan view of the display structure shown in FIG. 1.

FIG. 3 is a side cross-sectional view of the display structure shown in FIG. 1.

FIG. 4 is a schematic cross-sectional view of the display structure shown in FIG. 1 and including a spacing assembly.

FIG. 5 is a schematic cross-sectional view of the display structure shown in FIG. 1 including another example spacing assembly.

FIG. 6 is a flow chart illustrating an example method of making the display structure shown in FIG. 1.

FIG. 7 illustrates an example method of identifying bounds of display portions for making the display structure shown in FIG. 1.

FIG. 8 is a front plan view of an exemplary distal display portion of the display structure shown in FIG. 1.

FIG. 9 is a front plan view of another example display portion of the display structure shown in FIG. 1.

FIG. 10 is a front plan view of another example display portion of the display structure shown in FIG. 1.

FIG. 11 is a front plan view of another example display portion of the display structure shown in FIG. 1.

FIG. 12 is a front plan view of another example display portion of the display structure shown in FIG. 1.

FIG. 13 is a front plan view of an example proximal display portion of the display structure shown in FIG. 1.

FIG. 14 is a front plan view of another example display structure.

FIG. 15 is a perspective view of another example display system.

FIG. 16 is a front plan view of another example display structure.

FIG. 17 is a perspective view of another example display structure.

FIG. 18 is a front plan view of another example display structure.

FIG. 19 is a perspective view of the example display structure shown in FIG. 18.

FIG. 20 is a schematic diagram of an exemplary computing device that can be used to implement aspects of the present disclosure.

### DETAILED DESCRIPTION

Various embodiments will be described in detail with reference to the drawings, wherein like reference numerals represent like parts and assemblies throughout the several views. Reference to various embodiments does not limit the scope of the claims attached hereto. Additionally, any examples set forth in this specification are not intended to be limiting and merely set forth some of the many possible embodiments for the appended claims.

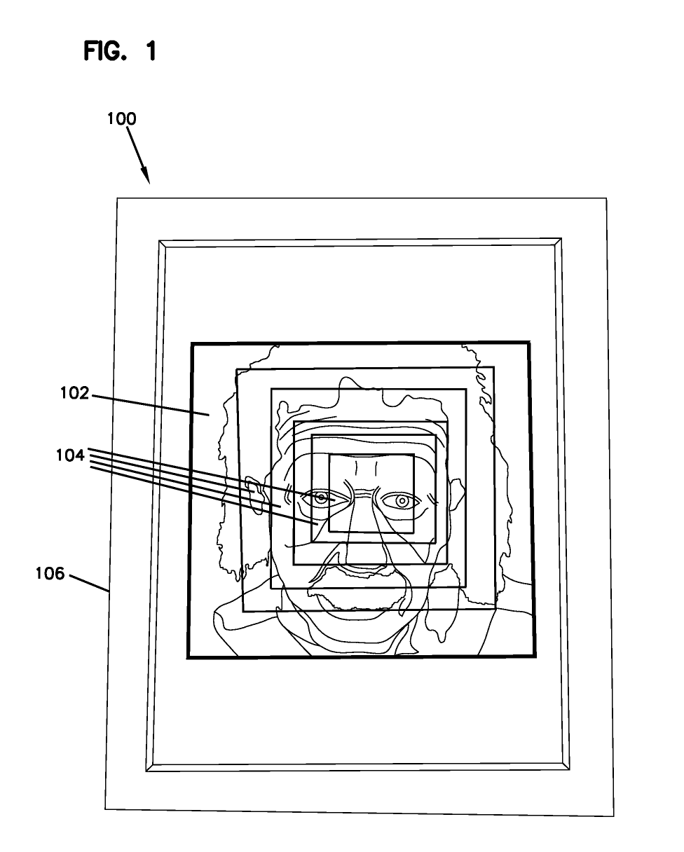

FIG. 1 is perspective view of an example three dimensional display system 100. In this example, the display system 100 includes a three dimensional display structure 102 including multiple display portions 104, and a support structure 106.

The three dimensional display structure 102 provides a unique three dimensional representation of a two dimensional image, by the stacked arrangement of multiple display portions 104. Each of the display portions 104 includes portions of an original two dimensional image. In this example, each display portion 104 is progressively smaller than an adjacent display portion 104, and when assembled form a structure reminiscent of a stepped pyramid.

In some embodiments, the display portions 104 are formed of at least one sheet of material. An example of a material is a sheet of paper. A more specific example is a sheet of photographic printer paper, such as having a gloss or matte finish. Other examples of possible materials include paper-based materials, such as poster board, paper board, cardboard, fiberboard, card stock, and the like; wood and wood-based materials, such as plywood, particle board, and the like; fabric; foam; plastic; acrylic; printable edible sheets or any other material onto which an image can be applied. An image is applied onto or arranged on the sheet of material. In some embodiments, the image is printed with a printer. In other possible embodiments, the image is painted, drawn, etched, applied, adhered, or otherwise formed on the material.

The display portions 104 are separated from each other by one or more spacers, not visible in FIG. 1, but illustrated and described in more detail herein.

In some embodiments, the display structure 102 is supported by a support structure 106. In this example, the support structure 106 is a picture frame including a transparent outer surface. Support structures can be open or enclosed. Open support structures do not include any pieces forward of display structure 102, while an enclosed support structure surrounds the display structure 102 and includes an at least partially transparent material to permit the display structure 102 to be viewed through the support structure 106. Other examples of support structures include a board, a frame, a shelf, a transparent plastic dome, a button, and a shadow box. In some embodiments the support structure includes one or more lights to illuminate the display structure 102 and/or to provide special lighting effects. Lighting effects can be used to further emphasize the three dimensionality of display structure 102.

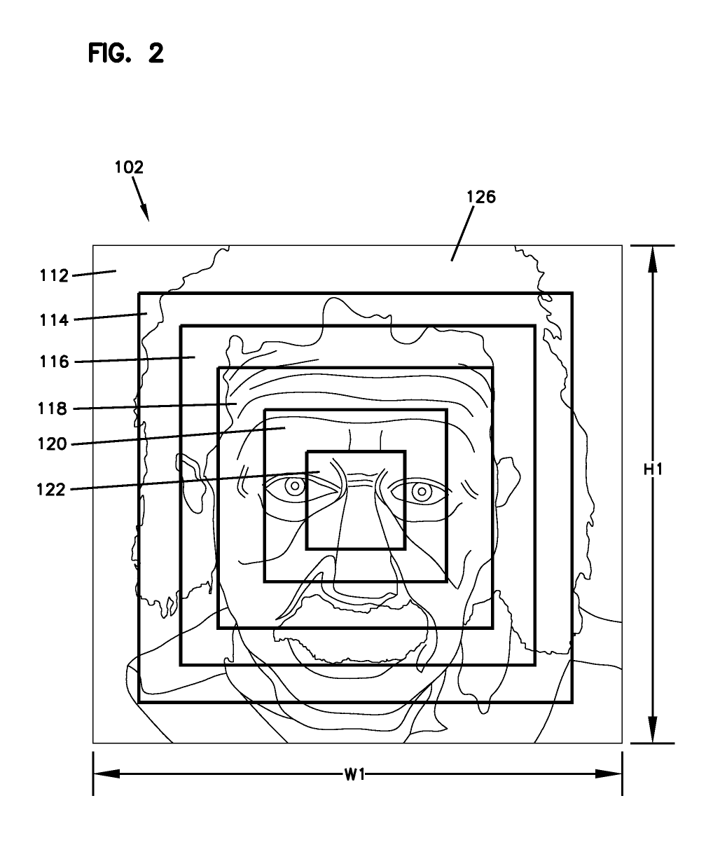

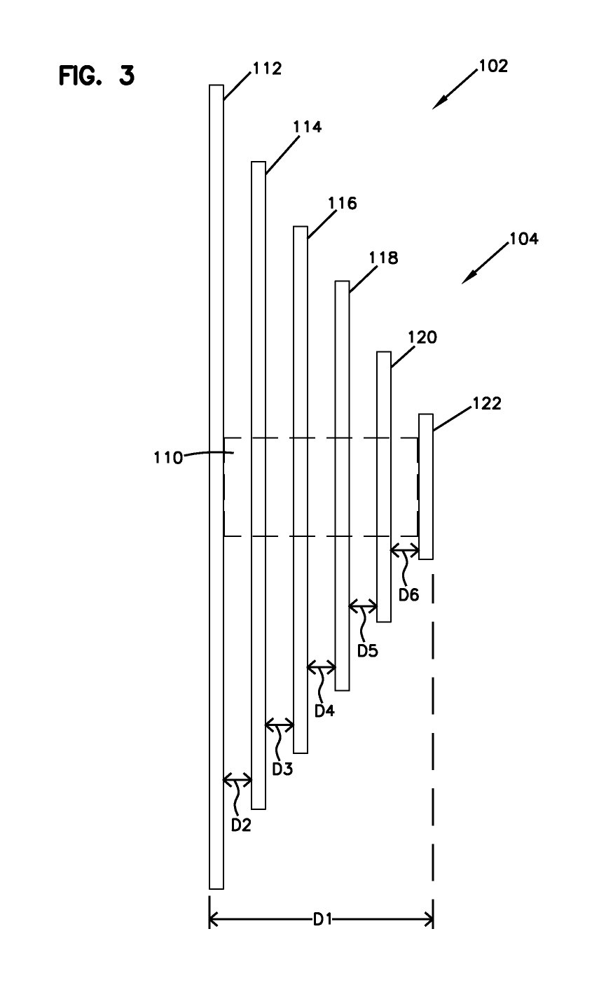

FIGS. 2-3 illustrate an example embodiment of the three dimensional display structure 102. FIG. 2 is a schematic front plan view and FIG. 3 is a side cross-sectional view.

The display structure 102 includes multiple display portions 104 and a spacing assembly 110 (FIG. 3) that spaces and supports the display portions 104 in a stacked and spaced arrangement. In some embodiments, the display portions 104 are?

The quantity of display portions 104 can be any number, such as in a range from three to ten, one hundred, or even one thousand or more. Some embodiments include three to fifteen display portions 104. Some embodiments include at least three, four, five, six, seven, eight, nine, or ten display portions 104.

The example shown in FIGS. 2-3 includes six display portions 104, including portions 112, 114, 116, 118, 120, and 122. In this example, the display portions 104 each have an outer periphery (defined by edges of the display portions 104) and a front surface on which portions of an image are visible. The front surface has a surface area bounded by the outer periphery. The surface area of each display portion 104 is less than an adjacent display portion 104, except for display portion 112 that forms the rearmost display portion. The surface area of each display portion 104 decreases from display portion 112 to display portion 122, such that display portion 112 has the largest surface area and display portion 122 has the smallest surface area. In some embodiments the display portion 112 is a most rearward, or proximal, of the display portions 104. In some embodiments the display portion 122 is the most forward, or distal, of the display portions 104.

Each display portion 104 includes at least a portion of an image 126. In the example described above, the portion of the image that is included on each display portion decreases from display portion 112 to display portion 122. When assembled as shown in FIG. 2, visible surfaces of display portions 104 collectively present portions of the image 126, such that when viewed from a direct frontal view as shown in FIG. 2, the entire image 126 is visible, with a three dimensional appearance due to the projection of serially assembled and overlapping display portions 104 toward the viewer. When viewed from an angle, a unique appearance is obtained that differs from appearance of the original image.

The display structure 102 can be made to have almost any desired size. In the example shown in FIG. 2, the display structure has an overall height H1 and width W1. In some embodiments, the display structure 102 is button sized, such as having a height H1 and a width W1 in a range from about 1 inch to about 3 inches. In some embodiments, the display structure 102 is portrait sized, such as having a height H1 and width W1 in a range from about 3 inches to about 12 inches. In some embodiments, the display structure 102 is poster sized, such as having a height H1 and a width W1 in a range from about 16 inches to about 40 inches. In some embodiments, the display structure 102 is life sized, such as having a height H1 and a width W1 in a range from about 2 feet to about 8 feet. In some embodiments, the display structure 102 is billboard sized, such as having a height H1 and a width W1 in a range from about 14 feet to about 60 feet. Other embodiments have other sizes outside or between these ranges.

Referring to FIG. 3, the display structure 102 includes a spacing assembly 110. The spacing assembly 110 can perform several functions, in some embodiments. The spacing assembly 110 supports the display portions 104 in a stacked and facing arrangement to each other. The spacing assembly 110 also supports the display portions in a spaced arrangement to each other. For example, display portion 114 is spaced from adjacent display portions 112 and 116. Display portion 116 is spaced from adjacent display portions 114 and 118. Display portion 118 is spaced from adjacent display portions 116 and 120. Display portion 120 is spaced from adjacent display portions 118 and 122. Display portion 122 is spaced from adjacent display portion 120. The spacing assembly 110 can also act to properly align display portions 104 in some embodiments.

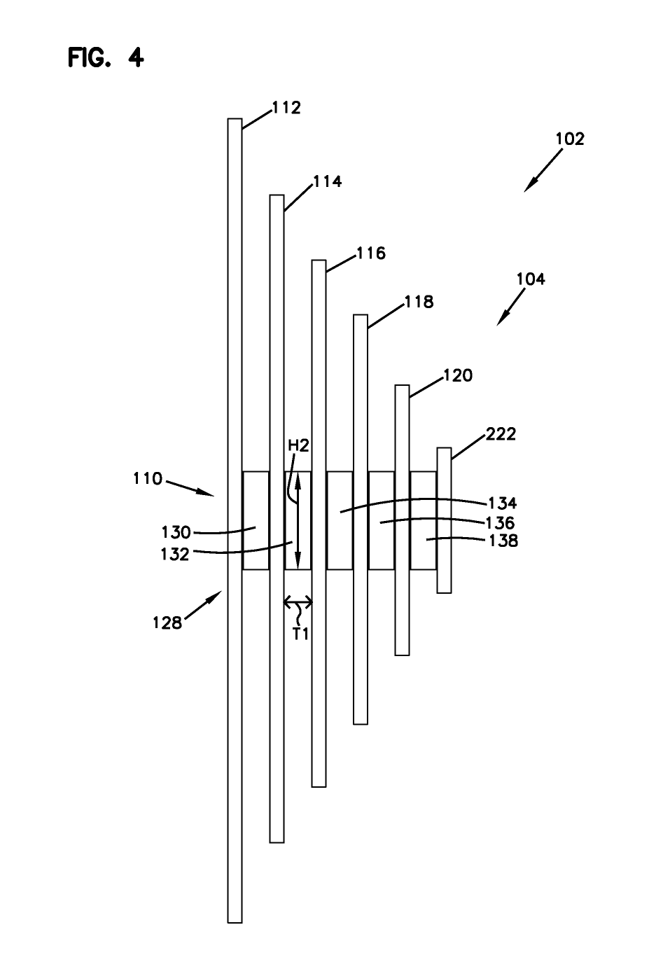

Exemplary embodiments of the spacing assembly 110 are illustrated and described in more detail with reference to FIGS. 4 and 5.

The display structure 102 can be made to have almost any desired depth. In the example shown in FIG. 3, the display structure 102 has an overall depth D1. In some embodiments, the depth is in a range from about 0.5 inches to about 12 inches. In some embodiments, the depth is in a range from about 1 inch to about 5 inches. Other embodiments have larger or smaller depths. For example, a billboard sized display structure 102 can have a depth D1 in a range from about 5 feet to about 20 feet or more.

Spacing assembly 110 provides proper spacing of adjacent display portions 104 of display structure 102, in some embodiments. In this example, D2 is the distance between display portions 112 and 114, D3 is the distance between display portions 114 and 116, D4 is the distance between display portions 116 and 118, D5 is the distance between display portions 118 and 120, and D6 is the distance between display portions 120 and 122. In some embodiments, the distances are the distance between adjacent display portions 104. In other embodiments the distances are the distances between front surfaces of adjacent display portions 104.

In some embodiments, the distances D2, D3, D4, D5, and D6 between adjacent display portions 104 are equal or substantially equal. In other embodiments, at least some of the distances are unequal. In some embodiments, the distances are in a range from about 0.2 inches to about 2 inches. In some embodiments the distances are the distances between front surfaces of adjacent display portions 104. In other embodiments, the distances are the spaces between adjacent display portions 104.

FIG. 4 is a schematic cross-sectional view of an example display structure 102 including an example spacing assembly 110. As previously described, the example includes multiple display portions 104, including display portions 112, 114, 116, 118, 120, and 122.

In this example, the spacing assembly 110 is formed of multiple spacer blocks 128. In this example, display structure 102 includes five spacer blocks 130, 132, 134, 136, and 138. Spacer blocks 128 are arranged between each adjacent display portion 104. For example, spacer block 130 is arranged between display portions 112 and 114, spacer block 132 is between display portions 114 and 116, spacer block 134 is between display portions 116 and 118, spacer block 136 is between display portions 118 and 120, and spacer block 138 is between display portions 120 and 122.

Spacer blocks 128 can be made of a variety of different materials. One example material is foam board, which is a good choice because it is a light material that is rigid, comes in a variety of colors, is easy to cut, and can be obtained in varying thicknesses. Other examples of spacer materials include acrylic, rubber, wood, and plastic. Spacer blocks 128 are typically connected to one or more display portions 104 with adhesive. In some embodiments, the spacer block 128 is pre-coated on one or both opposing surfaces with a stable adhesive from a manufacturer. The spacer block 128 is adhered to a display portion 104 by arranging the display portion 104 and the spacer block 128 together and applying a pressure to promoted adhesion.

Spacer blocks 128 of any desired thickness T1 can be used, and multiple spacer blocks 128 can be stacked together if additional thickness is desired. For example, in some embodiments a foam board having a thickness T1 of 3/16 inches is used. Other embodiments include spacer blocks 128 having a thickness in a range from about 0.2 inches to about 2 inches. Other embodiments include larger or smaller thicknesses. Further, some embodiments utilize spacer blocks 128 having multiple different thicknesses.

Spacer blocks 128 preferably have a height H2 and width (not visible in FIG. 4) that is less than the height and width of the smallest adjacent display portion 104 to which the spacer block 128 is connected. This allows portions of the larger adjacent display portion 104 to be visible when display structure 102 is viewed at an angle.

FIG. 5 is a schematic cross-sectional view of another example display structure 102 including another example spacing assembly 110. Similar to previously described embodiments, the example includes multiple display portions 104, including display portions 112, 114, 116, 118, 120, and 122.

One or more spacer apertures 140 are formed through at least some of display portions 104. In this example, spacer apertures 140 are formed through all of the display portions 104 (112, 114, 116, 118, and 120) except for the distal display portion 122. The spacer apertures 140 are used by the spacing assembly 110 as described below. In some embodiments, the spacer apertures 140 are carefully aligned in each display portion 104 so that they are positioned at the same place on each image. In this way, the spacer apertures 140 are not only used by the spacing assembly 110 for supporting and properly spacing display portions 104, but also to properly align the images on display portions 104.

In this example, the spacing assembly 110 includes one or more spacer rods 142 and fasteners 144. In some embodiments, spacing assembly 110 is an adjustable spacing assembly. In some embodiments, spacing assembly 110 is a variable distance spacing assembly.

Spacer rod 142 is typically a straight and substantially rigid rod having a strength suitable to support display portions 104 without significantly bending under the load. Spacer rod 142 can be made of a variety of materials, such as nylon, plastic, metal, or wood. Spacer rod 142 can be threaded or non-threaded. One specific example of a suitable spacer rod 142 is a threaded nylon rod.

Spacer rod 142 extends through spacer apertures 140 that are formed in at least some of the display portions 104.

Fasteners 144 are used in some embodiments to firmly hold display portions 104 in an orientation perpendicular to a longitudinal axis of spacer rod 142. An example of fasteners 144 is a threaded nut, such as made of nylon. Other fasteners are used in other embodiments, such as o-rings, clips, washers, gaskets, rubber bands, adhesive, or other types of fasteners or combinations of fasteners. In some embodiments, spacer blocks are used in conjunction with spacer rod 142, with or without fasteners 144.

When a threaded spacer rod 142 and threaded nuts are used, display portions can be adjustably positioned at any desired location along the length of spacer rod 142. The threaded washers are then arranged on either side of the display portions 104 to hold the display portions 104 at the desired positions. For example, in the embodiment shown in FIG. 5, a spacing between display portion 112 and display portion 114 has been selected to be less than the spacing between other display portions.

Fasteners 144 having various thicknesses can be used to permit display portions to be arranged as close together or as far apart as desired, while maintaining adequate strength and side to properly support the display portion in the desired orientation. In the illustrated example, larger fasteners 144 are used to support display portions 112 and 114 than are used to support display portions 120 and 122.

Because the entire front surface of distal display portion 122 is entirely visible when viewed from the front, it is typically undesirable for the spacer rod 142 to extend entirely through display portion 122. In some embodiments, rather than forming a spacer aperture 140 in distal display portion 122, a fastener is connected to a rear surface of distal display portion 122 to support the distal display portion 122. For example, adhesive is used to connect fastener 144 and an end of spacer rod 142 to the rear surface of distal display portion 122. A bracket or other fastener can also or alternatively be used in some embodiments.

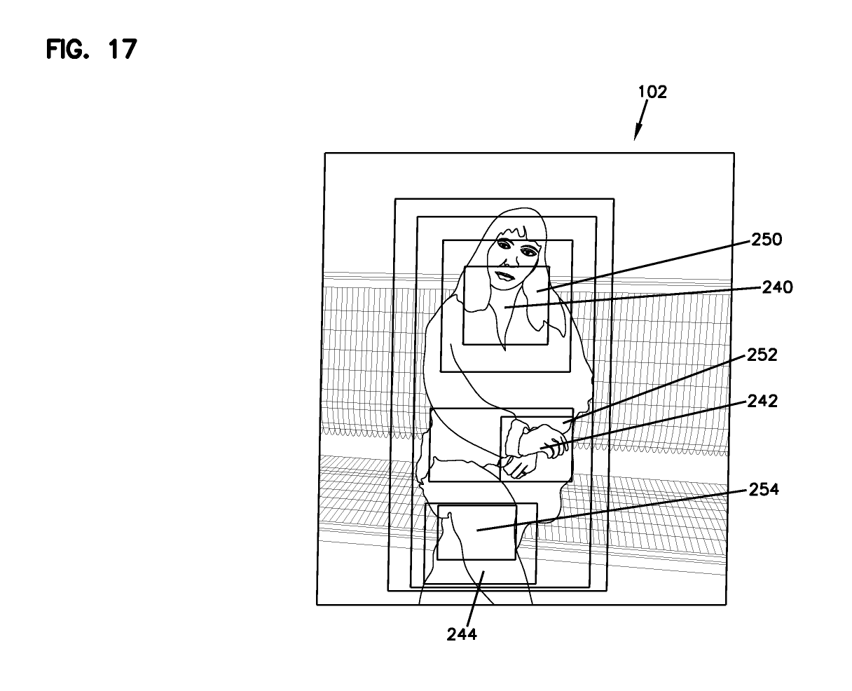

In some embodiments, multiple spacer rods 142 are used. Multiple spacer rods 142 can be useful to provide added strength to reduce the chance of spacer rods 142 bending, cracking, or breaking Multiple spacer rods 142 also improve the resistance of spacing assembly 110 to rotation of display portions 104. Further, multiple spacer rods 142 can be used to permit the inclusion of multiple distinct distal display portions 122 (which each contain a portion of the image sometimes referred to herein as a focal point). An example of a display structure 102 including multiple focal points is illustrated and described in more detail with reference to FIG. 17.

FIG. 5 also illustrates another example embodiment of display portions 104. In this example, each display portions 104 is formed of multiple layers, including a protective layer 152, an image layer 154, and a protective layer 156.

Image layer 154 is a layer that contains the respective portion of the original image. An example of the image layer 154 is a sheet of photographic printer paper having an image printed on one side, and being cut to the appropriate shape and size. Other suitable examples are described herein.

Some embodiments further include protective layers 152 and 156 arranged on one or both opposing surfaces of image layer 154. The protective layers 152 and 156 can provide one or more benefits, such as to improve the durability of image layer 154, improve the strength and structural stability of image layer 154, and to prevent or reduce the amount of moisture that comes into contact with image layer 154. When moisture contacts image layer 154, the moisture can cause damage to the image layer 154, and can cause warping of the image layer. The protective layers 152 and 156 reduce or prevent such damage. The protective layers 152 and 156 also make the image layers 154 easier to clean, as the protective layers 152 and 156 can be gently wiped or brushed without being damaged. An example of protective layers 152 and 156 is a lamination layer. Other possible protective layers include, for example, contact paper, glass, plastic, or a variety of possible coatings.

In an alternative embodiment, layer 152 is a backer layer. The backer layer is a relatively rigid material having suitable strength to support the image layer 154 in a substantially planer and perpendicular orientation to the longitudinal axis of the spacer rod 142. Examples of a backer layer 152 are a sheet of wood, metal, plastic, cardboard, or foam board. It is preferable that a thickness of a backer layer 152 be thin, or alternatively be recessed from side edges of image layer 154 to reduce the visibility of edges of the backer layer 152. Some embodiments include both a backer layer and a protective layer 152.

Some embodiments further include protective layer 156, which is applied on image layer 154 to protect image layer 154. The protective layer 156 may also, or alternatively, provide added structural stability to image layer 154. An example of protective layer 156 is a transparent material such as a sheet of lamination. Other possible protective layers include, for example, contact paper, glass, plastic, or a variety of possible coatings.

Some embodiments of display structure 102 further include a backer 160. An example of backer 160 is a sheet of foam board, such as having a thickness of 3/16 inches, although other thicknesses and other materials can be used in other embodiments. The foam board can be useful for coupling the display structure 102 to another object (e.g., a wall) or to a support structure 106 (shown in FIG. 1). In some embodiments the backer 160 has an adhesive surface for connecting the backer 160 to the proximal display portion 112.

An attachment mechanism 162 is provided in some embodiments for connecting the display structure 102 to another object or to a support structure 106. An example of the attachment mechanism is a hook and loop fastener. Other examples of attachment mechanisms include adhesive, tape, a hanger, a nail, a pin, a magnet, a bracket, or other fasteners or devices.

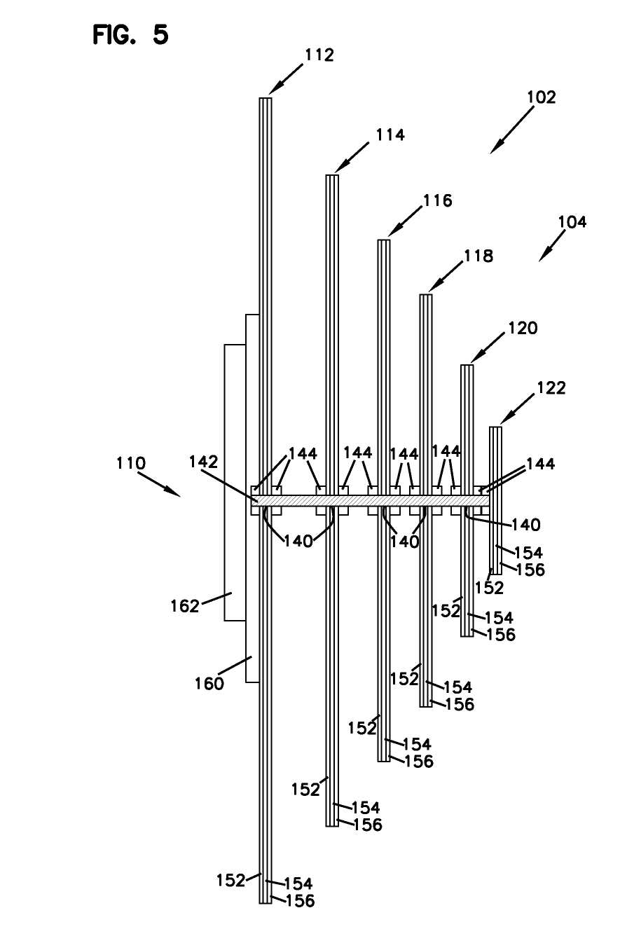

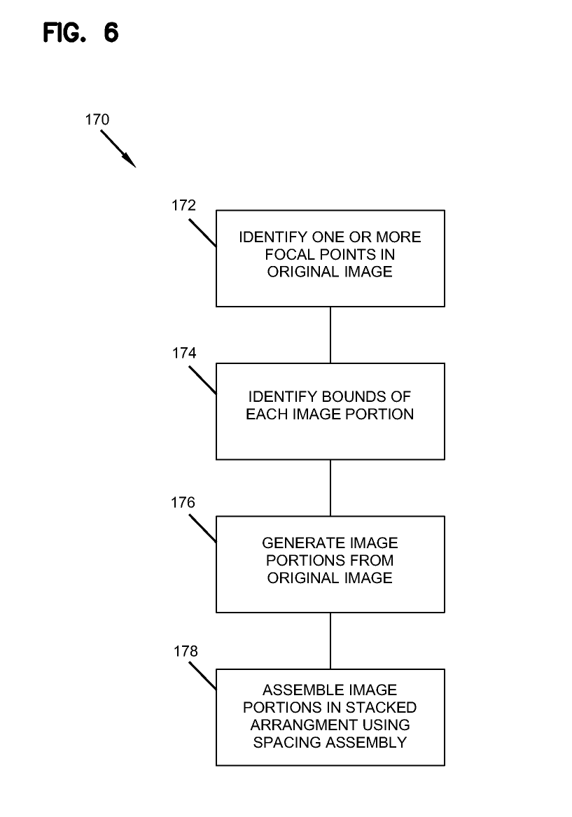

FIG. 6 is a flow chart illustrating an example method 170 of making display structure 102. In this example, the method 170 includes operations 172, 174, 176, and 178.

An original image is first obtained. The original image may be in various forms, such as a digital image, a printed image, or a photograph. The original image can be received at a web server, such as through a web site user interface that prompts the user to upload the image from a user computing device. In other embodiments, the image is received in a variety of other manners, such as through an e-mail message, a memory card, and a short message service message from a mobile device. In some embodiments, the image is a physical image that is sent in the mail, or brought to a kiosk or store by the user. The image can be scanned to generate a digital image, if desired.

After the original image is obtained, an operation 172 is performed in some embodiments to identify one or more focal points in the original image.

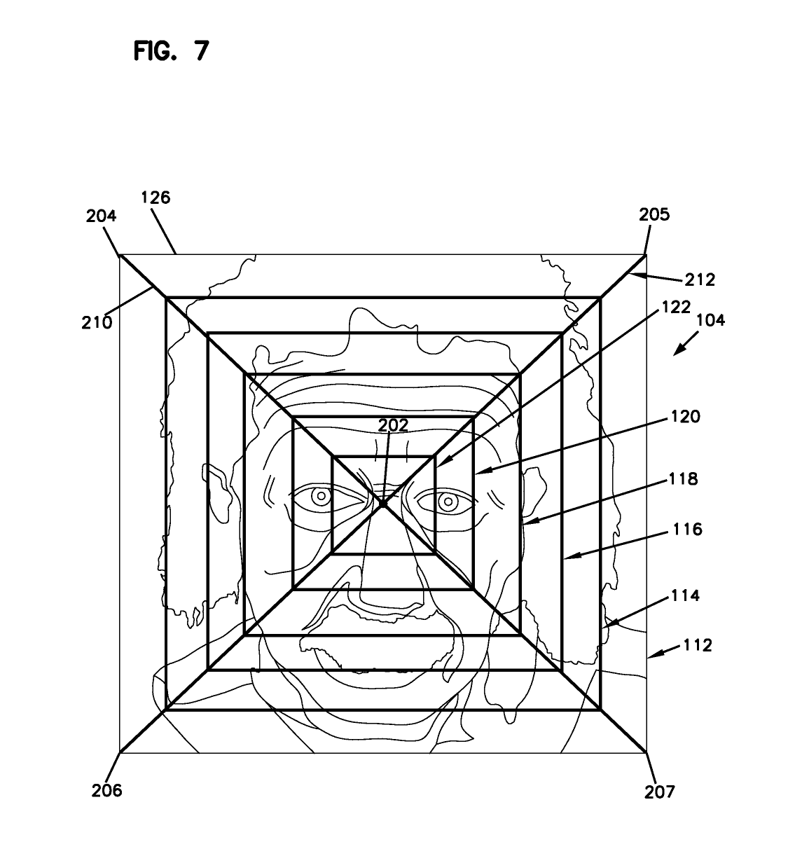

A focal point is a portion of the original image that is to be emphasized by the display structure 102. More specifically, in some embodiments, the focal point is a portion of the image that will be displayed on the distal display portion (e.g., 122 shown in FIG. 2). Because the distal display portion is the furthest projection of display structure 102, the viewer's attention is drawn to the portion of the image that is displayed on the distal display portion. An example of a focal point is shown in FIG. 7.

After the focal point has been identified, operation 174 is performed to identify bounds of each display portion. Examples of operation 174 are described in more detail with reference to FIG. 7.

Once the bounds of each display portion have been identified, operation 176 is performed to generate the display portions from the original image. In some embodiments, multiple copies of the same image are obtained, such as by printing or copying of the original image. Each display portion is then cut from a copy of the original image at the bounds identified in operation 174. In some embodiments the copies include the entire original image, while in other embodiments the copies include only the portions of the original image that are required for each respective display portion.

In some embodiments, prior to cutting display portions, all but one of the copies of the original image are stacked together and one or more spacer apertures (e.g., 140 shown in FIG. 5) are formed through the display portions at once. This ensures that all of the spacer apertures are properly aligned.

In some embodiments, operation 176 further includes additional steps, such as applying one or more protective layers to the display portion, such as by laminating the image layer.

Once all of the display portions have been generated, operation 178 is performed to assemble display portions in a stacked arrangement using a spacing assembly. For example, in some embodiments spacer blocks 128 are connected to display portions such as illustrated in FIG. 4. In another embodiment, one or more spacer rods 142 are inserted through spacer apertures 140 and fasteners 144 are used to securely fasten display portions 104 at the desired positions along the one or more spacer rods 142. The distal display portion is also connected adjacent to ends of the one or more spacer rods 142, such as using an adhesive.

In some embodiments, a backer layer is connected to a rear surface of a proximal display portion. Further, a fastening device can also be coupled to backer layer, if desired.

After the display structure 102 has been assembled, the display structure 102 can be installed in or connected to a support structure, such as a frame, a shadow box, or other enclosure or support.

FIG. 7 illustrates an example method 190 of identifying bounds of display portions 104 from an original image 126. Method 190 is also an example of operation 174, shown in FIG. 6.

In some embodiments, operations illustrated in FIG. 7 are performed with a computing device. For example, in some embodiments a computing device includes a processing device and a computer readable storage media. The computer readable storage media stores the original image in digital form, and also includes data instructions, which when executed by the processor, implement an image manipulation software program. Examples of image manipulation software programs are Corel DRAW® X5 and PHOTO-PAINT™ X5 distributed by Corel Corporation of Ottawa, Ontario, Canada. The data instructions cause the processor to perform one or more of the following operations. In some embodiments, the computing device receives input from a user. In some embodiments, the computing device prompts the user to provide the input.

After an original image is obtained, one or more focal points 202 are identified in the image 126. In this example, a single focal point has been selected—a point directly between the eyes of the subject. Any other focal point can alternatively be selected, such as the tip of the nose, an eye, both eyes, a chin, or any other point on the subject. In this example, the focal point is arranged directly at the center of the original image, but other embodiments include focal points that are not directly in the center of the image 126. If desired, the original image can be cropped, trimmed, or otherwise shaped into any desired size or shape.

Image 126 includes corners 204-207.

Guide lines 210 and 212 are used in some embodiments, to assist in the identification of boundaries of display portions 104. In this example, guide lines 210 and 212 are positioned on the original image extending diagonally between corners 204-207 and through focal point 202. More specifically, guide line 210 is positioned between corners 204 and 207, and guide line 212 is positioned between corners 205 and 206. Since focal point 202 is directly in the center of the image, the guide lines 210 and 212 can be positioned to extend from corner to corner while also passing through focal point 202.

In other embodiments, focal point 202 is not positioned in the center of image 126. In such embodiments, guide lines 210 and 212 cannot extend from corner to corner and also pass through focal point 202. As a result, in some embodiments the guide lines are positioned to extend through one of the corners (e.g., 204 and 205) and through focal point 202 without crossing through the other corners (e.g., 207 and 206). Alternatively, in some embodiments guide lines 210 and 212 are positioned to cross through focal point 202 and to be aligned at predetermined angles to a vertical or horizontal centerline of the image 126, such as at 45 degree angles to the centerline.

Once guide lines 210 and 212 have been positioned, display portions 104 are next identified using the guide lines. In some embodiments, a quantity of display portions 104 to be used is first selected. In this example, the quantity is selected to be six display portions.

Next, boundaries for each of the display portions 104 are identified. For example, a proximal display portion 112 is identified as the entire original image 126, or a portion of the original image 126. Subsequent display portions are defined as having boundaries within the bounds of the proximal display portion 112, such that each subsequent display portion has an area smaller than the prior display portion. The distal display portion is positioned to include the focal point 202 and a portion of the image surrounding the focal point. In some embodiments, all display portions 112 include the focal point 202.

In one example, identification of boundaries of display portions 104 is performed using the image manipulation software. For example, rectangles are drawn on the original image to identify the boundaries of each display portion. In some embodiments, the rectangles are positioned so that corners of the rectangles intersect with guide lines 210 or 212.

In some embodiments, at least portions of copies of the original image are included on or visible at a surface of each display portion 104. The copies of the original image are congruent or substantially congruent in some embodiments. For example, in some embodiments the portions of the original image are aligned such that they appear from a front view to be a single copy of the original image. In some embodiments, substantially congruent images include common points (e.g., the focal point 202) that are aligned, such as along a common axis. In some embodiments, the portions are aligned within manufacturing tolerances. In other embodiments, the portions are aligned within +/−1%, and in other embodiments, the portions are aligned within +/−5%.

In some embodiments, positioning of the boundaries of each display portion is performed automatically by the computing device. Once the computing device knows the focal point and the number of display portions that are desired, boundaries of the display portions can be positioned by dividing a distance from the focal point to an edge of the original image by the number of display portions. This is repeated for each edge until all four edges have been identified for each display portion.

Once boundaries have been identified, the guide lines are removed and display portions are then generated. As one example, each display portion is printed using the computing device, image manipulation software, and a printer.

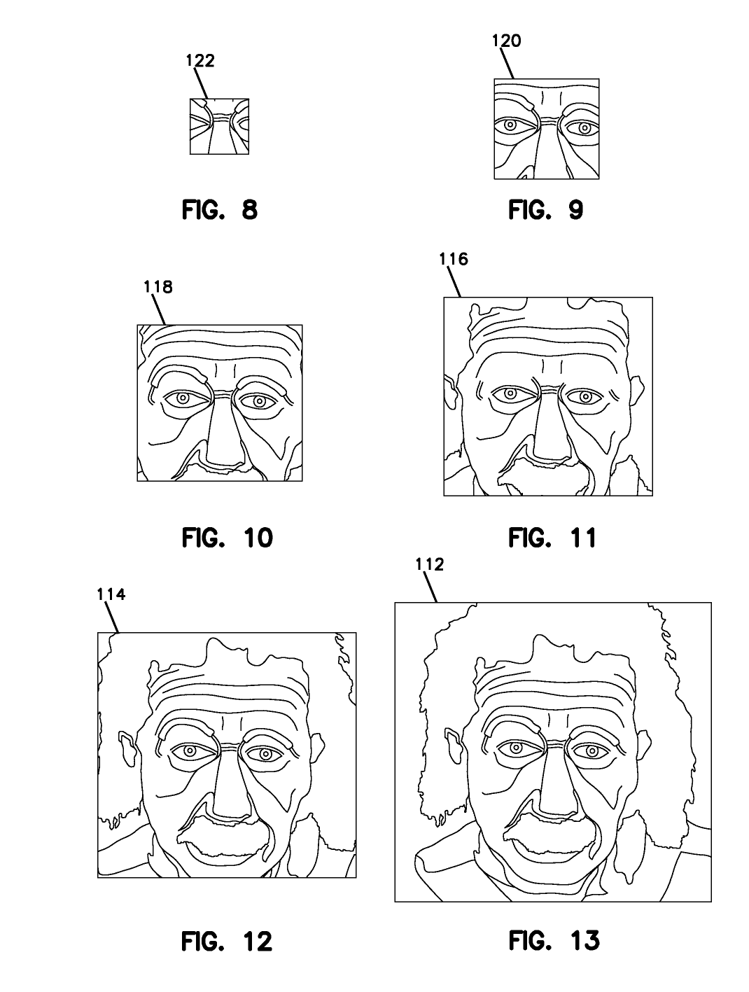

For example, once the guide lines have been removed, a copy of the original image can be printed on a sheet of photographic paper, including the boundary lines. The printed image is then used to generate distal display portion 122 by cutting edges of the distal display portion along the boundary lines. The complete distal display portion 122 is shown in FIG. 8.

Next, the boundary lines for the distal display portion 122 are removed, and second copy of the original image is printed, including the remaining boundary lines. This printed copy is then used to generate display portion 120, by cutting edges of the display portion 120 along the appropriate boundary lines. The complete display portion 120 is shown in FIG. 9.

The boundary lines for display portion 120 are then removed, and a third copy of the original image is printed, including the remaining boundary lines. This printed copy is then used to generate display portion 118, by cutting edges of the display portion 118 along the appropriate boundary lines. The complete display portion 118 is shown in FIG. 10.

The boundary lines for display portion 118 are then removed, and a fourth copy of the original image is printed, including the remaining boundary lines. This printed copy is then used to generate display portion 116, by cutting edges of the display portion 116 along the appropriate boundary lines. The complete display portion 116 is shown in FIG. 11.

The boundary lines for display portion 116 are then removed, and a fifth copy of the original image is printed, including the remaining boundary lines. This printed copy is then used to generate display portion 114, by cutting edges of the display portion 114 along the appropriate boundary lines. The complete display portion 114 is shown in FIG. 12.

The boundary lines for display portion 114 are then removed, and a sixth copy of the original image is printed, including the remaining boundary lines (if any). This printed copy is then used to generate proximal display portion 112, by cutting edges of the display portion 112 along the appropriate boundary lines (if any). Alternatively, in some embodiments the distal display portion 112 is the entire original image, and does not require cutting. The complete proximal display portion 112 is shown in FIG. 13.

Assembly of the display structure can then proceed as discussed with reference to FIG. 6.

FIGS. 8-13 illustrate front plan views of display portions 104, including one of display portions 122, 120, 118, 116, 114, and 112, as discussed herein. Each display portions 104 includes at least a portion of an original image visible on a front surface, and a periphery defined by one or more edges. In this example, each of the display portions 104 also includes the point on the original image defined as the focal point 202 (FIG. 7).

The front surface of each display portions 104 has a surface area. In this example, each display portion has a different surface area, where the proximal display portion 112 has the greatest surface area, and each successive display portion has a smaller surface area, with distal display portion 122 having the least surface area.

In some embodiments, display portions 104 have different shapes. Although the examples illustrate display portions 104 having rectangular shapes, other embodiments have other shapes. For example, some embodiments have rounded corners. Yet other embodiments have circular, triangular, or other more complex shapes. In some embodiments display portions have a shape that matches or follows one or more features of the image (i.e., a part of a subject, such as an edge of a face, etc.).

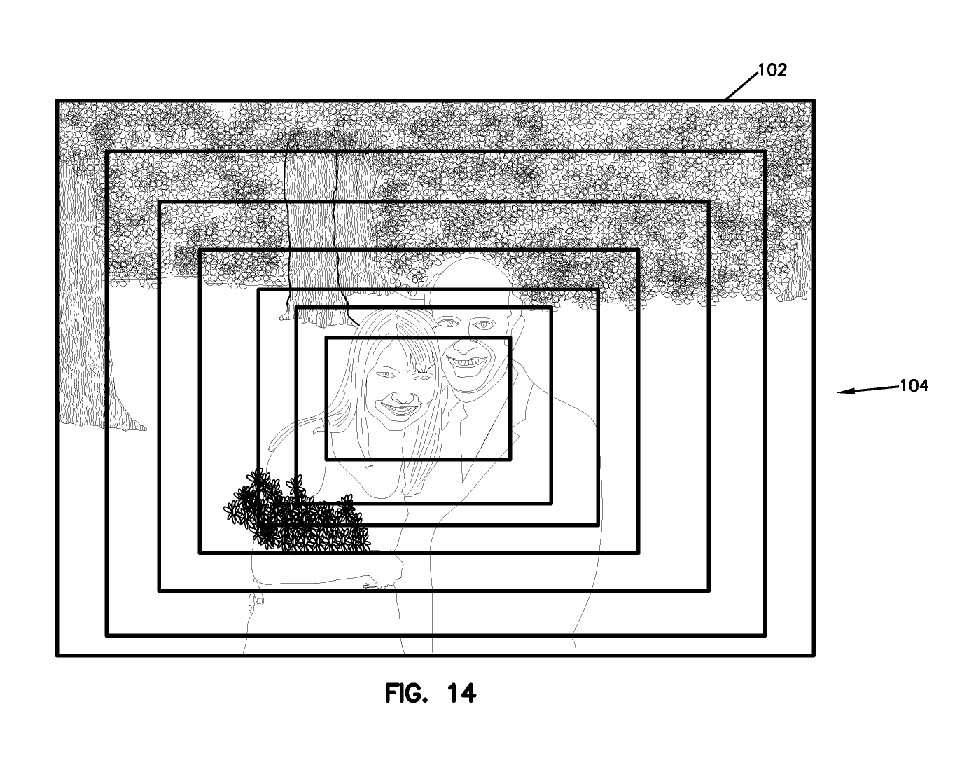

FIG. 14 is a front plan view of another example display structure 102. In this example, the display structure 102 includes multiple display portions 104, which each includes a portion of an original image 220.

The original image 220 is a photograph of two people standing outside with a natural background.

In this example, the display structure 102 includes seven display portions 104, with a proximal display portion in the back and a distal display portion in the front. Each display portion 104 is spaced from adjacent display portions 104 by a spacing assembly not visible in FIG. 14.

The display structure 102 includes a focal point that was selected near to the faces of the two subjects. As a result, the distal display portion includes the majority of one subject's face, and about half of the other subjects face.

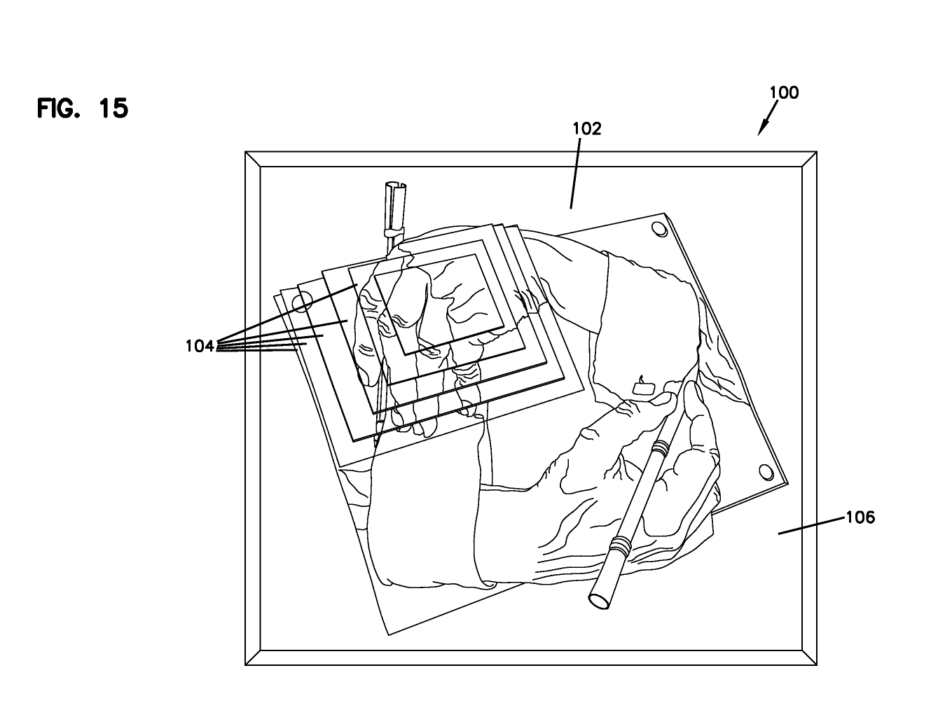

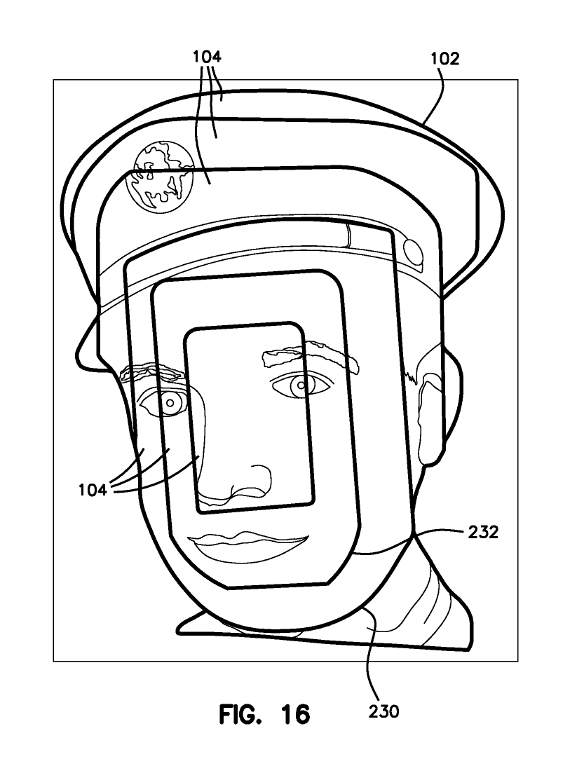

FIG. 15 is a perspective view of another example display system 100, including a display structure 102, multiple image displays 104, and a support structure 106. In this example, the support structure 106 is an open frame. In this example, the display system 100 is a large poster-sized display system.

In this example, display system 100 is made from an original image that is a well known lithograph by M. C. Escher, titled “Drawing Hands.”

This example illustrates how the focal point (located on one of the depicted hands) and display portions 104 do not need to be arranged at the center of the display system 100, or at the center of the original image. In contrast, the focal point is positioned in an upper left quadrant of the display system 100, and the image displays 104 (other than the rear-most proximal image display) are largely located in the same quadrant. This example also illustrates a proximal image display that is much larger than any of the other image displays 104.

FIG. 16 is a front plan view of another example of a display structure 102. The display structure 102 is formed of an original image of a portrait of a person's head and wearing a hat. The display structure 102 is formed of six display portions 104.

This example illustrates several variations that can be included in some embodiments. In some embodiments the background is removed from each display portion, so that the display portion includes only portions of the subject of the original image. The proximal display portion, for example, has been cut to remove any portion of the image that does not depict the subject.

Also, in some embodiments corners of each display portions 104 are rounded to remove sharp corners.

In addition, some embodiments include display portions that are contoured along features depicted in the image to enhance the blending of the display portions. For example, curves 230 and 232 have been formed. Curve 230 follows the jaw line of the subject, and curve 232 follows the curve of the cheek of the subject. Other shapes have also been made, such as along the subjects hat, etc.

FIG. 17 is a perspective view of another example of a display structure 102. This example illustrates a display structure having multiple focal points 240, 242, and 244, and therefore also including multiple distinct distal display portions 250, 252, and 254.

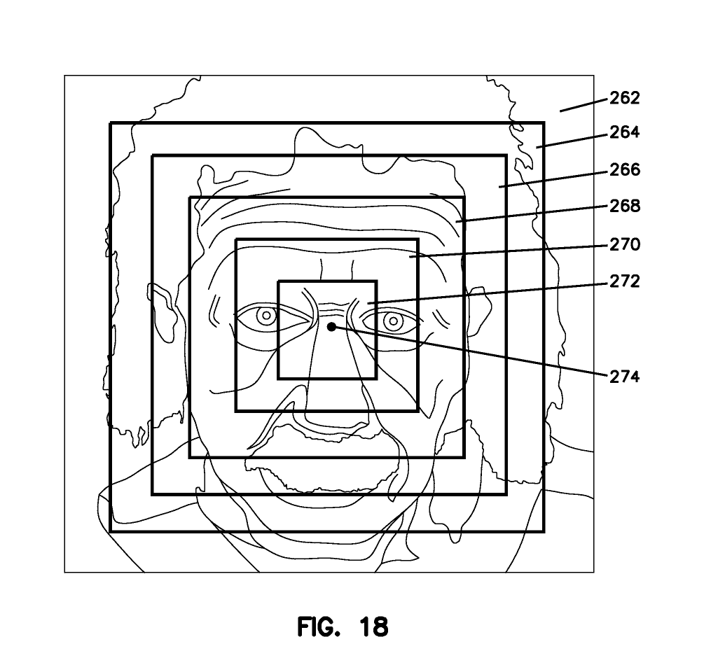

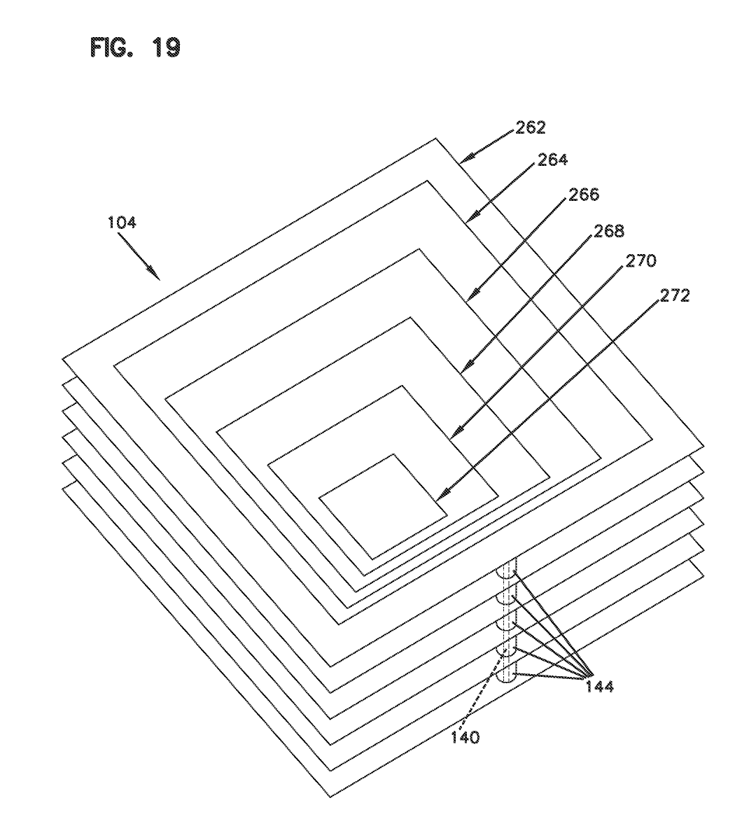

FIGS. 18-19 illustrate another example of a display structure 102. FIG. 18 is a front plan view of the display structure 102, and FIG. 19 is a perspective view of the display structure 102. The display structure 102 includes multiple display portions 104.

In this example, the structure of the display portions is reversed, such that the focal point 274 is displayed only on the rear-most (proximal) display portion 272, and each successive display portion is spaced out from the adjacent display portion 104, where the distal display portion 262 has the furthest projection.

In this example, boundary lines of each display portion define an internal boundary, rather than an external boundary as in the example shown in FIG. 7. As a result, the display portions 104 are formed to remove all portions of the image within the boundary lines, including the focal point, while maintaining the remaining portions of the image.

In this example, support structures (e.g., 140 and 144) are arranged behind portions of the distal display portion 262. For example, the support structure may include one structure on the left-hand side and another on the right-hand side to support both sides of the display structure 102.

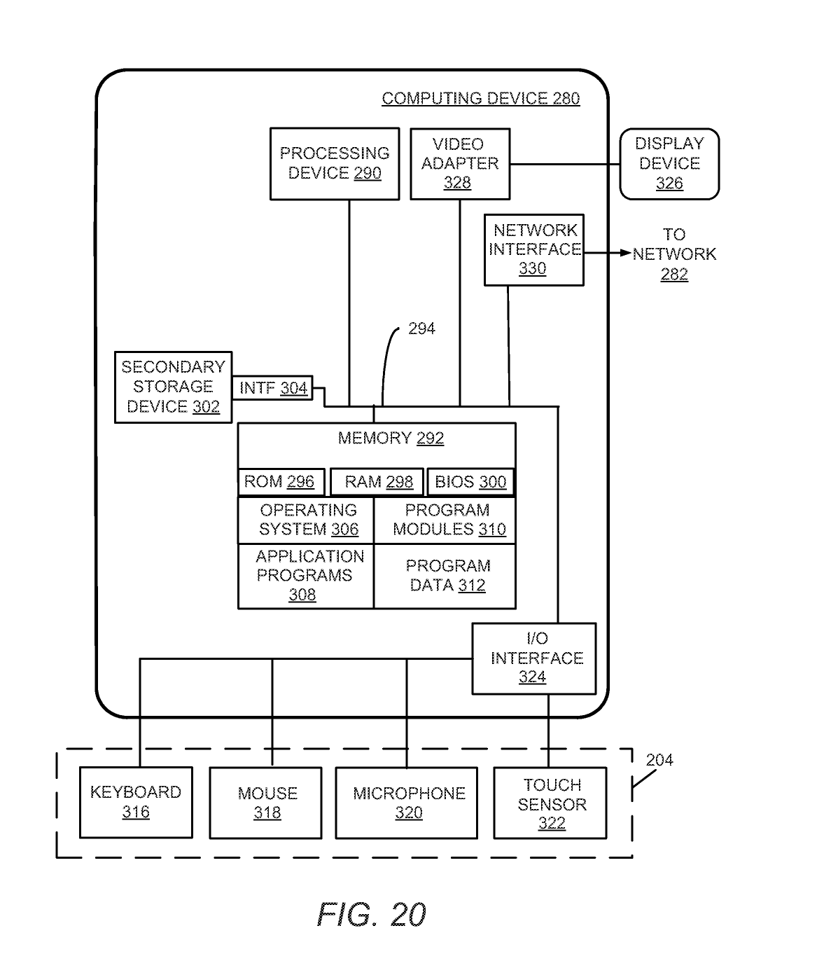

FIG. 20 illustrates an exemplary architecture of a computing device that can be used to implement aspects of the present disclosure. The computing device illustrated in FIG. 20 can be used to execute an operating system, application programs, and software modules, described herein. The computing device 280 can be a personal computer or a server computer that is in data communication with other computing devices across network 282.

The computing device 280 includes, in some embodiments, at least one processing device 290, such as a central processing unit (CPU). A variety of processing devices are available from a variety of manufacturers, for example, Intel or Advanced Micro Devices. In this example, the computing device 280 also includes a system memory 292, and a system bus 294 that couples various system components including the system memory 292 to the processing device 290. The system bus 294 is one of any number of types of bus structures including a memory bus, or memory controller; a peripheral bus; and a local bus using any of a variety of bus architectures.

Examples of computing devices suitable for the computing device 280 include a desktop computer, a laptop computer, a tablet computer, a mobile computing device (such as a smart phone, an iPod® or iPad® mobile digital device, or other mobile devices), or other devices configured to process digital instructions.

The system memory 292 includes read only memory 296 and random access memory 298. A basic input/output system 300 containing the basic routines that act to transfer information within computing device 280, such as during start up, is typically stored in the read only memory 296.

The computing device 280 also includes a secondary storage device 302 in some embodiments, such as a hard disk drive, for storing digital data. The secondary storage device 302 is connected to the system bus 294 by a secondary storage interface 304. The secondary storage devices 302 and their associated computer readable media provide nonvolatile storage of computer readable instructions (including application programs and program modules), data structures, and other data for the computing device 280.

Although the exemplary environment described herein employs a hard disk drive as a secondary storage device, other types of computer readable storage media are used in other embodiments. Examples of these other types of computer readable storage media include magnetic cassettes, flash memory cards, digital video disks, Bernoulli cartridges, compact disc read only memories, digital versatile disk read only memories, random access memories, or read only memories. Some embodiments include non-transitory media.

A number of program modules can be stored in secondary storage device 302 or memory 292, including an operating system 306, one or more application programs 308, other program modules 310 (such as the software engines described herein), and program data 312. The computing device 280 can utilize any suitable operating system, such as Microsoft Windows™, Google Chrome™, Apple OS, and any other operating system suitable for a computing device. Other examples can include Microsoft, Google, or Apple operating systems, or any other suitable operating system used in tablet computing devices.

In some embodiments, a user provides inputs to the computing device 280 through one or more input devices 314. Examples of input devices 314 include a keyboard 316, mouse 318, microphone 320, and touch sensor 322 (such as a touchpad or touch sensitive display). Other embodiments include other input devices 314. The input devices are often connected to the processing device 290 through an input/output interface 324 that is coupled to the system bus 294. These input devices 314 can be connected by any number of input/output interfaces, such as a parallel port, serial port, game port, or a universal serial bus. Wireless communication between input devices and the interface 324 is possible as well, and includes infrared, BLUETOOTH® wireless technology, 802.11a/b/g/n, cellular, or other radio frequency communication systems in some possible embodiments.

In this example embodiment, a display device 326, such as a monitor, liquid crystal display device, projector, or touch sensitive display device, is also connected to the system bus 294 via an interface, such as a video adapter 328. In addition to the display device 326, the computing device 280 can include various other peripheral devices (not shown), such as speakers or a printer.

When used in a local area networking environment or a wide area networking environment (such as the Internet), the computing device 280 is typically connected to the network 282 through a network interface, such as an Ethernet interface 330. Other possible embodiments use other communication devices. For example, some embodiments of the computing device 280 include a modem for communicating across the network.

The computing device 280 typically includes at least some form of computer-readable media. Computer readable media includes any available media that can be accessed by the computing device 280. By way of example, computer-readable media include computer readable storage media and computer readable communication media.

Computer readable storage media includes volatile and nonvolatile, removable and non-removable media implemented in any device configured to store information such as computer readable instructions, data structures, program modules or other data. Computer readable storage media includes, but is not limited to, random access memory, read only memory, electrically erasable programmable read only memory, flash memory or other memory technology, compact disc read only memory, digital versatile disks or other optical storage, magnetic cassettes, magnetic tape, magnetic disk storage or other magnetic storage devices, or any other medium that can be used to store the desired information and that can be accessed by the computing device 280.

Computer readable communication media typically embodies computer readable instructions, data structures, program modules or other data in a modulated data signal such as a carrier wave or other transport mechanism and includes any information delivery media. The term “modulated data signal” refers to a signal that has one or more of its characteristics set or changed in such a manner as to encode information in the signal. By way of example, computer readable communication media includes wired media such as a wired network or direct-wired connection, and wireless media such as acoustic, radio frequency, infrared, and other wireless media. Combinations of any of the above are also included within the scope of computer readable media.

The computing device illustrated in FIG. 20 is also an example of programmable electronics, which may include one or more such computing devices, and when multiple computing devices are included, such computing devices can be coupled together with a suitable data communication network so as to collectively perform the various functions, methods, or operations disclosed herein.

It should be appreciated that aspects of embodiments described herein can be combined with or modified by any of the aspects of other embodiments described herein to result in yet further embodiments.

The various embodiments described above are provided by way of illustration only and should not be construed to limit the claims attached hereto. Those skilled in the art will readily recognize various modifications and changes that may be made without following the example embodiments and applications illustrated and described herein, and without departing from the true spirit and scope of the following claims.

What is claimed is:

1. A display structure for displaying a two dimensional image in three dimensions, the structure comprising:
a first display portion having a substantially planar first surface, the first surface having a first area and depicting thereon at least a portion of the two dimensional image;
a second display portion having a substantially planar second surface substantially parallel to and spaced from the first surface, the second surface having a second area less than the first area and depicting thereon at least the portion of the two dimensional image; and
a third display portion having a substantially planar third surface substantially parallel to and spaced from the second surface, the third surface having a third area less than the second area and depicting thereon at least the portion of the two dimensional image, wherein the portions of the two dimensional image depicted on the first, second, and third display portions are aligned with each other.

2. The display structure of claim 1, further comprising a spacing assembly coupled to and supporting the first, second, and third display portions in a spaced arrangement.

3. The display structure of claim 2, wherein the spacing assembly comprises a plurality of spacing blocks.

4. The display structure of claim 2, wherein the spacing assembly comprises at least one rod and a plurality of fasteners.

5. The display structure of claim 4, wherein the rod is a threaded nylon rod and the fasteners are threaded nylon nuts.

6. The display structure of claim 4, wherein a space between the first display portion and the second display portion is different than a space between the second display portion and the third display portion.

7. The display structure of claim 1, wherein the two dimensional image depicted on the first, second, and third display portions are substantially congruent.

8. A method of making a display structure for displaying a two dimensional image in three dimensions, the method comprising:
obtaining the two dimensional image;
generating a plurality of differently sized display portions from copies of the two dimensional image; and
arranging the display portions in a stacked and spaced arrangement in which the display portions are substantially congruent.

9. The method of claim 8, wherein generating a plurality of differently sized display portions comprises:
identifying at least one focal point of the two dimensional image;
positioning guide lines on the two dimensional image intersecting the focal point;
determining a quantity of display portions; and
determining boundaries of the display portions using the guide lines.

10. The method of claim 9, wherein generating a plurality of differently sized display portions is performed at least partially automatically by a computing device.

11. The method of claim 9, further comprising printing copies of the two-dimensional image including at least one boundary of at least one display portion, and cutting out the at least one display portion along the boundary.

12. The method of claim 11, further comprising:
forming at least one spacer aperture in at least some of the display portions; inserting a threaded nylon rod into the at least one spacer aperture of at least some of the display portions; and
securing at least some of the display portions to the nylon rod with fasteners.

13. The method of claim 12, wherein distances between adjacent display portions are irregular.

14. The method of claim 8, wherein a surface area of each display portion decreases from a rearward display portion to a forward display portion, such that the forward display portion has the least surface area.

15. The method of claim 8, wherein at least some of the display portions include an interior cutout portion through which at least an adjacent one of the display portion is visible.

16. The method of claim 15, wherein a surface area of each display portion decreases from a rearward display portion to a forward display portion, such that the forward display portion has the least surface area.

17. The method of claim 8, wherein obtaining the two dimensional image comprises receiving the two dimensional image uploaded by a user to a web server through a web site user interface.

18. The method of claim 17, wherein obtaining the two dimensional image comprises receiving the two dimensional image from the user through at least one of: an e-mail message, a memory card, and a short message service message from a mobile device.

19. The method of claim 8, wherein arranging the display portions in a stacked arrangement comprises arranging the display portions in a nested stack.
